(19) United States
(12) Patent Application Publication
(10) Pub. No.: US 2005/0110010 A1
(43) Pub. Date: May 26, 2005

(54) Opto-electronic element with a metallized carrier

(75) Inventors: Matthias Winter, Regensburg (DE); Georg Bogner, Lappersdorf (DE); Stefan Gruber, Bad Abbach (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg, DE (US)

(21) Appl. No.: 10/952,138

(22) Filed: Sep. 28, 2004

(30) Foreign Application Priority Data
Sep. 30, 2003 (DE) 103 45 415.2
Oct. 14, 2003 (DE) 103 47 737.3

(51) Int. Cl. H01L 29/08

(52) U.S. Cl. 257/40

(57) ABSTRACT

In an optoelectronic component, having a semiconductor body (1) which includes a substrate (2) and a layer system (3) deposited on the substrate (2), a main surface of the semiconductor body (1) on the opposite side from the substrate (2) being secured to a support (4) by means of a soldered join (7), and the support (4) having a metallization (5) on the side facing the semiconductor body (1), wherein the metallization (5) is silver-free. Also disclosed is an optoelectronic component having a thin-film semiconductor body (8) which is secured to a support (4) by means of a soldered join (7), and the support (4) has a metallization (5) on the side facing the semiconductor body (8), in which the metallization (5) is silver-free.

### CROSS-REFERENCE TO RELATED APPLICATIONS

The present patent application claims the priority of German Patent Applications 10345415.2-11 filed Sep. 30, 2003 and 10347737.3-33 filed Oct. 14, 2003, the content of disclosure of which is hereby incorporated by reference.

### FIELD OF THE INVENTION

The invention relates to an optoelectronic component having a thin-film semiconductor body which is secured to a support by means of a soldered join, and the support has a metallization on the side facing the semiconductor body.

### BACKGROUND OF THE INVENTION

When producing optoelectronic components using thin-film technology, a semiconductor layer system is first of all grown on a growth substrate, is then applied to a new support, and then the growth substrate is detached. In the context of the invention, the remaining semiconductor layer system is to be understood as meaning a thin-film semiconductor body. Thin-film technology on the one hand has the advantage that growth substrates, in particular growth substrates which are suitable for the production of nitride compound semiconductors, and are relatively expensive, can be reused. Furthermore, this process has the advantage that the removal of the original substrate eliminates its drawbacks, such as for example a low electrical conductivity and high absorption of the radiation detected or generated by the optoelectronic component. This makes it possible to increase the efficiency of LEDs, in particular their brightness. An LED of this type is known, for example, from WO 02/084749, the content of which is hereby incorporated by reference.

A further technology used to produce highly efficient LEDs is what is known as the flip-chip technique. A component of this type is disclosed, for example, by WO 01/47039 A1. This document describes a radiation-emitting semiconductor chip, which is secured to a support at the opposite side from the growth substrate of the semiconductor layers.

In the case of optoelectronic components produced using thin-film technology or flip-chip technology, in which a semiconductor body is secured by means of a soldered join to a support body, which may, for example, be a leadframe or a submount (e.g. a semiconductor wafer), support bodies which have a suitable metallization layer for producing a soldered join applied to their surface are often used.

Examples of supports used include leadframes made from the base material copper, which are provided with a metallization of silver. It has been found that with components of this type, in power operation there is a high risk of short-circuiting of the functional layers. Furthermore, there is a risk of mechanically unstable soldered joins.

### SUMMARY OF THE INVENTION

One object of the present invention is to provide an optoelectronic component using thin-film and/or flip-chip technology which is distinguished by a high level of reliability.

This and other objects are attained in accordance with one aspect of the invention directed to an optoelectronic component having a semiconductor body which includes a substrate and a semiconductor layer system deposited on the substrate, a main surface of the semiconductor body on the opposite side from the substrate being secured to a support by means of a soldered join, wherein the support has a metallization on the side facing the semiconductor body, and wherein this metallization is silver-free.

Another aspect of the invention is directed to an optoelectronic component having a thin-film semiconductor body which is secured to a support by means of a soldered join, and the support has a metallization on the side facing the semiconductor body, wherein this metallization is silver-free.

If silver-coated leadframes are used for a component mounted by flip-chip technology or a component using thin-film technology, there is a risk of the silver layers being exposed to high electrical field strengths on account of the physical proximity to the functional semiconductor layers of the semiconductor body, which can lead to silver migration. The silver migration can give rise to short-circuiting of the optoelectronic component. A further disadvantageous effect of the migration of silver may be the formation of a silver-rich phase in the solder layer, which is mechanically unstable and may therefore lead to the contact being broken.

The silver-free metallization advantageously avoids problems which have been described previously and may occur as a result of silver migration. In the context of the present invention, the term silver-free is also considered to encompass metallizations in which traces of silver can still be detected but which have no practical importance with regard to the problems of silver migration. The maximum tolerable silver content may, for example, be determined by service life tests, in particular by operation under high humidity, or by current cycle tests.

The metallization preferably contains Ni, NiAu, NiPAu, NiP or TiPt. The thickness of the metallization is advantageously 0.2 μm to 10 μm, particularly preferably 2 μm to 4 μm. In addition to being silver-free, the abovementioned materials are also distinguished by their good processing properties with regard to production of the soldered join to the semiconductor body or for the attachment of a wire bond for external contact-connection of the optoelectronic component.

In order in particular to prevent oxidation of the metallization, it is preferable for a layer of gold to be applied to the metallization. The thickness of the layer of gold is advantageously 0.05 μm to 1 μm, particularly preferably 0.15 μm to 0.30 μm. The layer of gold may, for example, be deposited by electroplating, in which case it may be advantageous for only those regions of the support which are intended to produce a soldered join to be provided with a metallization and the layer of gold, in order to save on cost.

The support is, for example, a leadframe. By way of example, a chip housing is formed around the leadframe. The chip housing preferably consists of plastic and may, for example, be produced by injection moulding.

Other suitable supports for the optoelectronic component include, for example, a submount, in particular a semiconductor wafer, or a PCB (Printed Circuit Board).

The optoelectronic component is in particular a radiation-emitting component, for example a light-emitting diode or a laser diode. The invention is particularly advantageous for radiation-emitting components based on nitride compound semiconductors; a nitride compound semiconductor is to be understood as meaning a nitride compound of elements from the third and/or fifth main groups, in particular GaN, AlGaN, InGaN, AllnGaN, AlN or InN. On account of the higher operating voltage of 2 V or more compared to radiation-emitting components based on other semiconductor materials, there is an especially high risk of silver migration in the case of these nitride compound semiconductors.

### BRIEF DESCRIPTION OF THE DRAWINGS

The invention is explained in more detail below on the basis of two exemplary embodiments in conjunction with FIGS. 1 and 2. In the drawings:

FIG. 1 shows a diagrammatically-depicted cross-section through a first exemplary embodiment of the invention, and

FIG. 2 shows a diagrammatically-depicted cross-section through a second exemplary embodiment of the invention.

### DETAILED DESCRIPTION OF THE DRAWINGS

Components which are identical or have an equivalent action are provided with identical reference numerals in the figures.

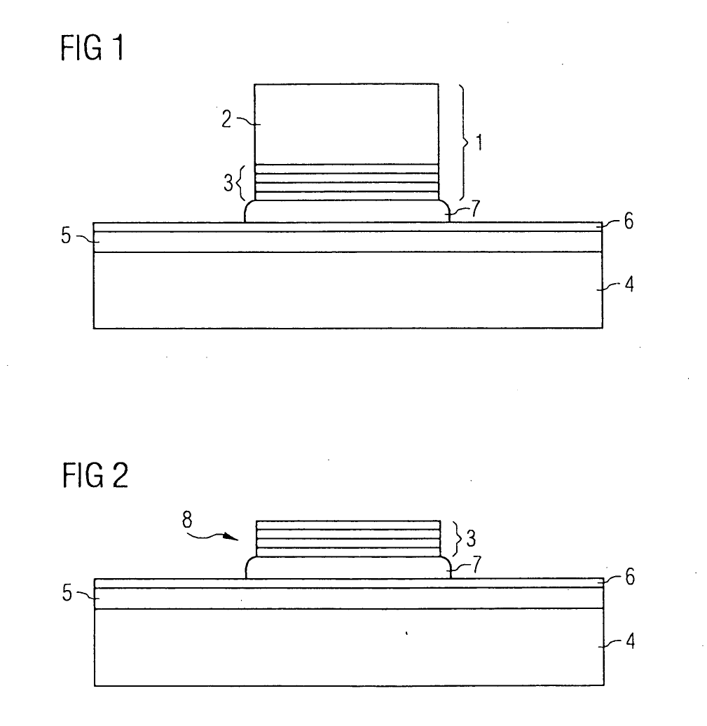

The optoelectronic component illustrated in FIG. 1 includes a semiconductor chip 1, which includes a substrate 2 and a layer system 3 deposited thereon. The substrate 2 is, for example, an SiC substrate or a sapphire substrate. The layer system 3 is in particular a semiconductor layer system which has been deposited epitaxially on the substrate 2 and, by way of example, includes a radiation-emitting active layer. In particular, this may be a radiation-emitting layer which contains a III-V compound semiconductor material, particularly preferably a nitride compound semiconductor.

The semiconductor chip 1 is secured to a support 4 by means of a soldered join 7. The support 4 is, for example, a leadframe, a submount or a printed circuit board. To ensure solderability, the support 4 is provided with a metallization 5, which according to the invention is silver-free. Examples of particularly suitable metallizations include Ni, NiAu, NiPAu, NiP or TiPt. A metallization 5 of this type avoids the problem of silver migration, which on the one hand causes short-circuiting of the semiconductor layers 3 of the optoelectronic component and on the other hand causes the soldered join 7 to be mechanically unstable as a result of the formation of a silver-rich phase within the soldered join 7.

The soldered join 7 may be formed by a contact layer system composed of a plurality of layers. The contact layer system comprises a layer of solder, containing, for example, a soft solder, in particular in a eutectic composition. It is preferable for the layer of solder to be applied to the semiconductor body 1 prior to production of the soldered join. However, it is also possible for the layer of solder to be applied to the support in structured form.

In a preferred embodiment, the contact layer system of the soldered join 7 may comprise further layers, for example a reflector layer facing the semiconductor layers 3, a barrier layer for isolating the reflector layer from the layer of solder, and/or layers which, for example, improve the bonding or wetting of the solder layer.

The metallization 5 of the support 4 preferably has a thickness of from 0.2 μm to 10 μm. It is advantageous for the metallization to be provided with a layer of gold 6, the thickness of which is from 0.05 μm to 1 μm. The layer of gold 6 is, for example, applied to the metallization by electroplating. The layer of gold 6 prevents oxidation of the metallization 5.

The metallization 5 and/or the layer of gold 6 are, for example applied to the entire surface of the support. Alternatively, the metallization 5 and/or the layer of gold 6 may be applied only to those regions of the support 4 which are intended to produce the soldered join. The structured application of the metallization 5 to the support 4 makes it possible to produce electrical connection regions which are electrically insulated from one another, so that, for example, both an n-contact and a p-contact of the semiconductor chip 1 can be connected to the support 4, in each case by means of a direct soldered join.

The exemplary embodiment of the invention illustrated in FIG. 2 differs from the embodiment illustrated in FIG. 1 by virtue of the fact that the semiconductor body 1 does not have a substrate, but rather is formed only by a thin-film semiconductor body 8 composed of a semiconductor layer system 3. The thin-film semiconductor body 8 is produced, for example, by a growth substrate which was originally present being detached after production of the soldered join between the semiconductor body 8 and the support 4. In particular, this may be a semiconductor body 8 which includes a semiconductor layer system 3 comprising nitride compound semiconductors, such as for example InGaAlN, which has been produced on a growth substrate formed from silicone carbide or sapphire, and the growth substrate has then been detached by means of a laser lift-off process. Otherwise, in particular with regard to the configuration of the metallization 5, the exemplary embodiment illustrated in FIG. 2 corresponds to the first exemplary embodiment, which was illustrated in FIG. 1.

The invention is not restricted by the description given on the basis of the exemplary embodiments. Rather, the invention comprises every novel feature and every combination of features, which in particular includes any combination of features in the patent claims, even if this feature or combination itself is not specifically mentioned in the patent claims or exemplary embodiments.

1. Optoelectronic component, having a semiconductor body (1) which includes a substrate (2) and a layer system (3) deposited on the substrate (2), a main surface of the semiconductor body (1) on the opposite side from the substrate (2) being secured to a support (4) by means of a soldered join (7), and the support (4) having a metallization (5) on the side facing the semiconductor body (1), characterized in that the metallization (5) is silver-free.

2. Optoelectronic component having a thin-film semiconductor body (8) which is secured to a support (4) by means of a soldered join (7), and the support (4) has a metallization (5) on the side facing the semiconductor body (8), characterized in that the metallization (5) is silver-free.

3. Optoelectronic component according to claim 1 or 2, characterized in that the metallization (5) contains Ni, NiAu, NiPAu, NiP or TiPt.

4. Optoelectronic component according to claim 1 or 2, characterized in that the thickness of the metallization (5) is from 0.2 μm to 10 μm.

5. Optoelectronic component according to claim 1 or 2, characterized in that a layer of gold (6) is applied to the metallization (5).

6. Optoelectronic component according to claim 5, characterized in that the thickness of the layer of gold (6) is 0.05 μm to 1 μm.

7. Optoelectronic component according to claim 5, characterized in that the layer of gold (6) is applied by electroplating.

8. Optoelectronic component according to claim 1 or 2, characterized in that the support (4) is a leadframe.

9. Optoelectronic component according to claim 8, characterized in that a chip housing is formed around the leadframe.

10. Optoelectronic component according to claim 1 or 2, characterized in that the support (4) is a submount, in particular a semiconductor wafer.

11. Optoelectronic component according to claim 1 or 2, characterized in that the support (4) is a printed circuit board (PCB).

12. Optoelectronic component according to claim 1 or 2, characterized in that the optoelectronic component is a radiation-emitting optoelectronic component.

13. Optoelectronic component according to claim 12, characterized in that the radiation-emitting optoelectronic component has a radiation-emitting active zone which contains a nitride compound semiconductor material.

14. Optoelectronic component according to claim 1 or 2, characterized in that the operating voltage of the optoelectronic component is 2 V or more.
